(19) United States
(12) Patent Application Publication
(10) Pub. No.: US 2003/0177436 A1
(43) Pub. Date: Sep. 18, 2003

(54) Transmission of encoded data packets with determination of the coding through explicit signalling by the receiver

(76) Inventors: Thomas Gruhn, Berlin (DE); Christoph Mecklenbraeuker, Wien (AT); Fariba Raji, Wien (AT); Frank Wegner, Berlin (DE)

Correspondence Address: STAAS & HALSEY LLP, SUITE 700, 1201 NEW YORK AVENUE, N.W., WASHINGTON, DC, 20005, US

(21) Appl. No.: 10/275,324

(22) PCT Filed: May 8, 2001
(86) PCT No.: PCT/DE01/01743

(30) Foreign Application Priority Data
May 8, 2000 (DE) 100 22 270.6

(51) Int. Cl. H04L 1/18; H03M 13/00

(52) U.S. Cl. 714/776

(57) ABSTRACT

The invention relates to a method and a radio communication system for the transmission of packet data units (SN#10, SN#11), by means of a radio interface in a radio communication system with at least one transmitter and at least one receiver, whereby the original data to be sent may be encoded with various codes to give various encoded units (CW1, CW2, CW3). Said various encoded units (CW1, CW2, CW3) are transmitted either consecutively or parallel to increase the redundancy in the receiver-side reconstruction of the original sent data and information on the underlying packet data units (SN#10, SN#11) is transmitted with the encoded units. According to the invention, the reconstruction of data may be expedited and improved by the transmission of information about the corresponding codes (CW1, Cw2, CW3) to the receiver with the encoded units and by a request from the receiver to the transmitter for the transmission of one or several selected encoded units.

The invention relates to a method for transmitting coded data packets in a radio communications system, and to a corresponding radio communications system.

In radio communications systems, messages and information (for example speech, picture information or other data) are transmitted by means of electromagnetic waves via a radio interface between a transmitting and a receiving station (base station and subscriber station, respectively).

In existing mobile radio networks according to the GSM standard (GSM: Global System for Mobile Communication), novel data services are currently being introduced, such as a packet data service GPRS (General Packet Radio Service). Third generation communications systems—such as the UMTS (Universal Mobile Telecommunications System) based on the UTRA standard (UTRA: Universal Terrestrial Radio Access)—are also envisaged for sending packet data units (PDUs). These packet data units are derived by segmentation and by addition of further control information from large data packets in higher layers or system levels (for example layer 3). In particular, packet data is transmitted asynchronously, or not synchronously, as a result of which the transmission durations and/or the transmission routes of individual successively transmitted packet data units may differ from one another. In order to identify the packet data units arriving at the receiver, these packet data units may be provided with an identification number or sequence number for the basic data (SN#i).

In packet data transmission, correct transmission of individual data packets is very important, since the packets are subsequently frequently assembled to form large blocks, whose correctness is checked once again at a higher administration level. If a packet is missing or a packet contains errors, the large block must be requested in its entirety once again from this higher administration level.

Since, in a large number of situations, data losses can occur during the transmission of packet data units, methods for data protection of transmitted data are known. These also include, in particular, coding methods and repetition methods, for example an automatic data repetition method with combinable coding for forward error correction FEC, whose abbreviated title is Hybrid ARQ Type II (ARQ: Automatic Repeat Request), which, after a first failed data transmission of a first coding unit, successively sends further supplementary coding units (second coding unit, third coding unit) as a repetition (retransmission). In this case, the redundancy generally increases from one repetition to the next, with a corresponding rise in the probability that the data packets can be reconstructed correctly at the receiving end.

EP 0 797 327 A2 describes adaptive hybrid ARQ methods, in which the coding rate selected by the transmitter depends either on the frequency at which the NACK signals received by the transmitter occur, or on the number of errors in the coding unit received most recently by the receiver. The receiver in this case transmits the number of errors together with an NACK signal to the transmitter.

Normally, there are a maximum number of n different coding units per data packet. After reaching the maximum intended redundancy, that is to say after transmission of the n-th coding unit, the transmission of an already transmitted coding unit can be repeated by the transmitter. The received signal from the renewed transmission (retransmission) can be combined with the received signal from the first transmission, for example using maximum ratio combining (recombination using the maximum possible ratio).

While the first coding unit consists, for example, of the unchanged or only slightly coded data, the data in the subsequently transmitted coding units (second, third) of a data packet are coded to a greater extent. Since, with these methods, the redundancy increases as the coding level rises, some information bits are generally saved, so that the second, third or n-th coding unit in some cases is not on its own sufficient to reconstruct the original data.

In some methods, for example Hybrid ARQ Type II, the receiver has to know which coding unit this is, in order to make it possible to carry out the appropriate decoding. With synchronous transmission, the association between the various repetitions can be reconstructed for this purpose by means of a chronological sequence of the reception times.

It is now possible for either the coding units or a positive or negative reception acknowledgement about successful reconstruction of the data packets (ACK or NACK, respectively) for the transmission to be lost.

In some systems, only one positive reception acknowledgement (ACK) is also sent. In these systems, it is not possible to distinguish from the reception acknowledgement between data packets which have not been received, which have not been transmitted, or which have been transmitted with errors. However, a negative reception acknowledgement can nevertheless be interpreted. For example, absence of reception acknowledgement for a data unit No. X when the reception acknowledgement is present for the data unit No. X−1 and the data unit No. X+1 makes it possible to deduce a negative reception acknowledgement (NACK) for the data unit No. X. In the case of non-synchronous packet data transmission, it is in general not possible to establish precisely the time at which data packets or signaling information is transmitted, or received data was transmitted. Generally, it is also possible for a signal to be subject to such severe interference that the receiver has no knowledge whatsoever of the transmission attempt, or cannot obtain any information at all from the received signal.

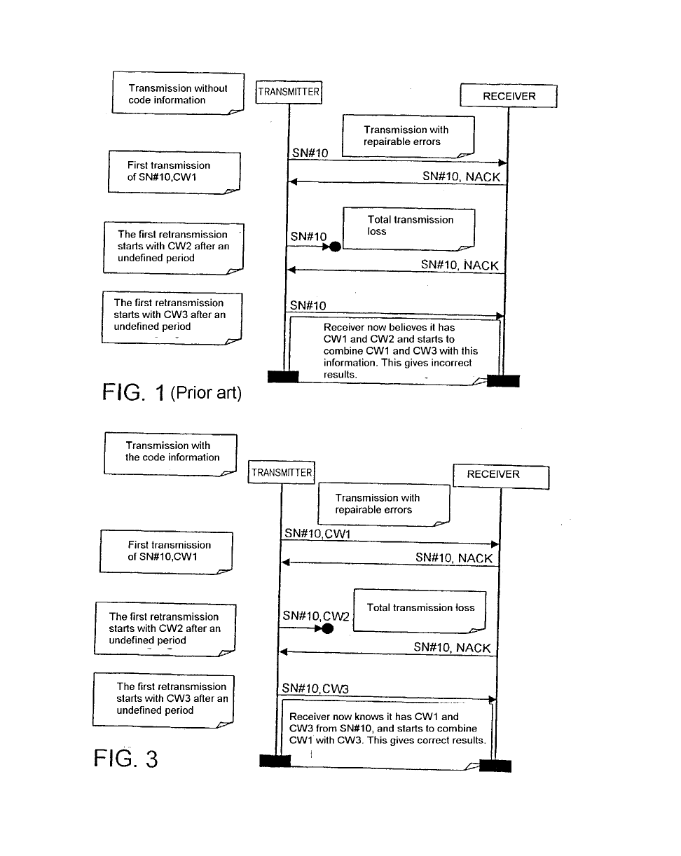

By way of example, FIG. 1 shows situations in which it is possible for problems to occur in the recombination of the original data, and in which the receiver has no knowledge of the associated code. If, for example, errors which are repairable occur during a first transmission of a data packet with the sequence number 10 (SN#10) or its first coding unit (SQ#10, CW1), then the receiver can transmit to the transmitter a negative reception acknowledgement (NACK) of the (incorrect) reception or of the failed decoding attempt. If the transmission of a subsequent coding unit which is carried out in response to this, for example of the second coding unit (SQ#10, CW2) of this data packet (SN#10), is subject to such severe interference that the receiver is not aware that it has not received a coding unit, then, after a request from the transmitter or spontaneously after a predetermined time interval has elapsed, it will request that the data packet be retransmitted. In the process, the receiver informs the transmitter by means of a negative acknowledgement signal or a negative reception acknowledgement (NACK), or else just by the lack of a positive reception acknowledgement, that the data in the data packet (SN#10) should be retransmitted. The initiation of this reception acknowledgement can be triggered using generally known methods, for example sending a bit list for a number of data packets, regular transmission, methods with timers or by drawing conclusions from successful transmissions.

One example is a bit list for reception acknowledgement with a start value=SN#1, a sequence=10111111101, where 1 means ACK and indicates a positive reception acknowledgement, 0 indicates NACK or no information relating to the transmission, and thus indicates a negative reception acknowledgement for the corresponding data packet. If the values in this case are SN#9=1, SN#11=1 and SN#10=0, the transmitter can interpret a negative reception acknowledgement NACK for the value SN#10. The transmitter does not know that the receiver did not receive the coding unit SN#10,CW2. All it can know is that the data packet SN#10 has not yet been successfully transmitted, as is necessary for successful decoding. On the assumption that only the second coding unit (SN#10, CW2) was received with errors, it thus transmits the third coding unit (SN#10, CW3). In contrast, the receiver does not know whether the second coding unit has now been sent with a delay, or the third coding unit has been sent on the basis of the last negative acknowledgement (NACK). In a corresponding way, it combines the first and third coding units as if the first and second coding units had been received. In consequence, the corresponding data packet is reconstructed incorrectly in situations such as this.

This example of treatment of the data thus takes place as in the case of synchronous transmission or as if it had been possible to identify the transmission sequence comprehensibly, that is to say it is known which coding unit was transmitted. In systems based on synchronous transmission, the acknowledgement (ACK or NACK) of the successfully or unsuccessfully received data packets is in this case produced immediately after receiving the data. The retransmission of the new coding unit of a data packet is then in consequence the first transmission which the receiver receives after transmitting the negative reception acknowledgement (NACK) for the coding unit that was transmitted with errors.

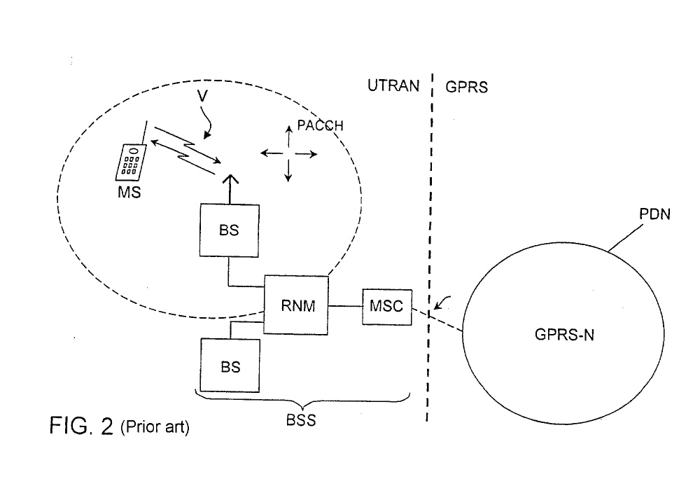

In the GPRS packet data service, it is possible to increase the coding during transmission. This increase is notified in a message channel (PACCH, FIG. 2) which can be used for this purpose and then applies for a time (for example 100 ms; ten data transmission blocks) which can be predetermined. In a further upgrade level, it is intended to create a capability to allow individual data blocks to be coded better as well. However, there is not yet any method that provides a suitable solution, in particular for the problem described above.

A further solution approach is to use suitable timers, in which case it would be necessary to define a maximum time period after which a transmission attempt should have taken place. However, in particular, this method would be associated with unnecessary waiting times.

The object of the invention is to provide a method and a radio communications system for transmitting coded packet data units or data packets in a radio communications system, in which the reconstructability of the original data can be improved and can be speeded up.

This object is achieved by the method having the features of patent claim 1, and by the communications system according to the features of patent claim 10.

Advantageous refinements are the subject matter of dependent claims.

The invention provides for the receiver to explicit signal to the transmitter a specific coding unit of a data packet which the transmitter should transmit to the receiver. This moves the decision as to which coding unit should be transmitted by the transmitter from the transmitter to the receiver. The latter can thus request the coding units required for reconstruction of the data packets more objectively, in accordance with its requirements. This relates in particular to situations where retransmissions are requested. It is thus possible to reduce the total number of coding units to be transmitted.

Since, according to one development of the invention, information relating to the corresponding code is transmitted to the receiver with the coding units, it is possible for the receiver to know directly which code to use for decoding. In particular, the receiver can know which coding unit has been received and can thus initiate a specific retransmission, especially in the situation of transmission with errors. In a situation in which the receiver has no information about the transmission of the first coding unit, for example in the presence of severe interference, it requests the first coding unit either after checking or else autonomously. The decision as to which coding unit should be transmitted can thus be made at the receiver end. The total number of required transmissions can advantageously be reduced by the capability to specifically request retransmissions of coding units with the same coding gain. This increases the system data rate. The data rate is increased in particular by the capability for the receiver to explicitly request the first, less heavily coded coding unit, of a data packet.

If the receiver requests a specific coding unit from the transmitter, the transmitter can advantageously transmit this coding unit without also at the same time transmitting the coding information. Furthermore, it is possible for the receiver to be able to distinguish the coding units in a data packet from one another even without any explicit identification by the transmitter, by comparing those coding units which have not been decoded with one another.

The capability to request a coding unit in conjunction with a positive or negative reception acknowledgement allows the use of communications system formats and facilities which need only minor adaptation.

The definition of a maximum number of repeated transmission attempts by the transmitter offers a simple termination criterion for the decoding attempt or for new requests for coding units by the receiver. In this case, after reaching the maximum number of repeated transmission attempts, at least one selected previously received coding unit can be explicitly requested once again in the receiver, so that it is nevertheless still possible to reconstruct the original data if the transmission of a specific coding unit fails all the time, by the repeated or additional request for other coding units. After reaching the maximum number of repeated transmission attempts, the sensible approach is to combine or replace a selected coding unit, which can be received as new, in the receiver. If the repetition is worse than the previous transmission of the same coding unit, the repeatedly transmitted coding unit can be rejected in the receiver. It is also possible to combine repetitions.

If the receiver directly requests a number (which can be predetermined) of coding units from the transmitter successively, the overall transmission time can be reduced to a minimum. Then initiating the decoding of the coding units makes it possible, after speedy transmission of all the required data, to identify in a single further method step whether and where there are transmission errors. This allows a subsequent specific request for new coding units, which have previously been received with errors, and this can once again be carried out quickly.

In particular, it is now in general possible for there to be any desired intervals between the transmissions of individual coding units. The method offers the capability, even in the case of non-synchronous transmission, to ensure that the receiver end is informed of the type of coding unit which it has received. In particular, the receiver end is also able to request specific coding units once again explicitly.

The receiver can reject the already received coding units at any time without any additional signaling complexity, and commence the decoding process from the start.

An exemplary embodiment will be explained in more detail in the following text with reference to the drawing, in which:

FIG. 1 shows a flowchart for the known transmission of coding units and corresponding reception acknowledgements;

FIG. 2 shows, schematically, a layout of an example of a known radio communications system;

FIG. 3 shows a flowchart for the transmission of coding units together with information about the corresponding code;

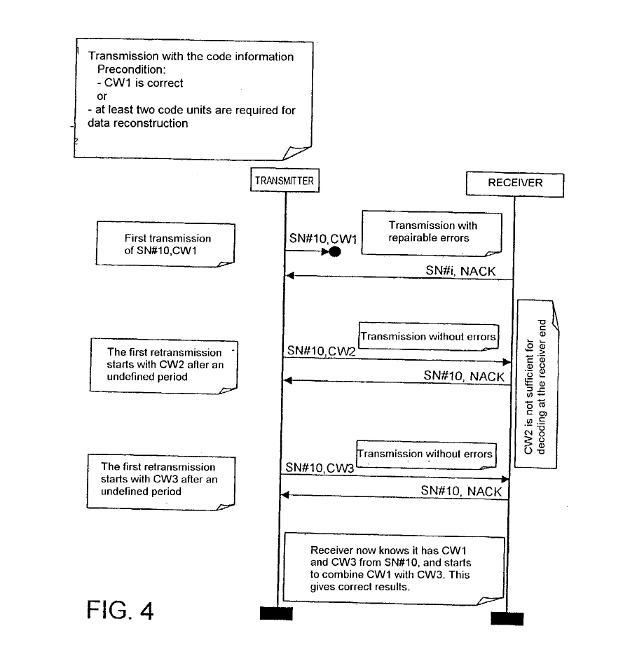

FIG. 4 shows an alternative flowchart for the transmission of coding units together with information about the corresponding code, and

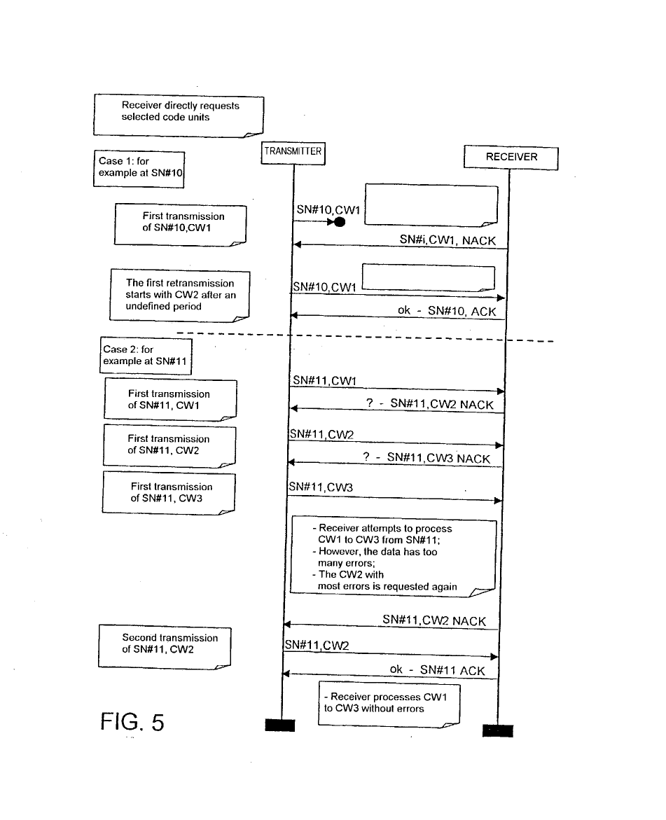

FIG. 5 shows a further flowchart for the transmission of coding units, in which the receiver requests specific coding units.

The communications system which is illustrated in FIG. 2 shows a radio communications network with devices which allow a packet data service (GPRS). A mobile station MS of a mobile subscriber is illustrated as an example of a stationary or mobile communications terminal, which is coupled without the use of wires via an air interface V to devices in a terrestrial UMTS radio network UTRAN (UMTS terrestrial radio access network) or to its base station system BSS, with fixed-position base stations BS and base station controllers. The connection for a packet-oriented communications network GPRS-N is provided in the UMTS radio network UTRAN via a mobile switching center MSC. The communications network GPRS-N has devices which are known per se for transmitting packet data between the mobile station MS and a packet data network PDN.

The first example of a method for transmitting coded transmission units, in particular for identifying coding methods for individual transmission units with a subsequent increase in redundancy, will now be explained using the illustration in FIG. 3.

When sending a data packet SN#10 which is to be transmitted, the transmitter sends to the receiver not only its identification number SN#10 but also information CWi, which indicates which code CWi was used in the preparation of the data packet SN#10.

In other words, each information packet and/or data packet to be transmitted should contain information to inform the receiver as to which redundancy part is currently being transmitted. In consequence, there may be any desired intervals between the transmissions.

The information CWi about the redundancy is advantageously attached to an already existing sequence number or to a header. This transmission of the information CWi about the redundancy can then be carried out together with the data SN#10.

However, alternatively or in addition, it is also possible to transmit the data SN#10 and the redundancy information CWi separately. By way of example, separate physical channels may be used for this purpose. This redundancy information CWi must then be linked to the data subsequently during the decoding or composition of the data blocks, and may also need to be linked to the header section of the data block. The coding for the information about the redundancy part is, of course, selected in accordance with the overall expected coding gain of the data.

The received coding data is composed, taking account of its redundancy level, in the receiver or in a device associated with the receiver. This is now available as a result of the transmission of the information CWi about the redundancy.

As before, the receiver can report whether the most recently received data block has been received correctly, and whether it has been possible to reconstruct the data without errors. The transmitter can now decide which redundancy level it will repeat, if repetition is necessary.

If the receiver has not received all the necessary data, it can also report to the transmitter directly or at a subsequent time in the course of a retransmission request which redundancy level it wishes to have transmitted during the next transmission.

FIG. 3 essentially shows the sequence of the transmission process described with reference to FIG. 1. After a first transmission, with errors, of the first coding unit SN#10, CW1, the receiver, in this case by way of example a base station BS, sends a negative reception acknowledgement SN#10, NACK back to the transmitter, in this case by way of example a mobile station MS. The example of transmission of the second coding unit SNlO#, CW2 is once again lost. By once again transmitting the negative reception acknowledgement SN#10, NACK, the receiver requests retransmission of data SN#10 from the transmitter. If the transmitter now once again sends the third coding unit SN#10, CW3 of the data packet SN#10 to the receiver, then the receiver uses the information CW3, which is also transmitted and relates to the redundancy level of the transmitted data, to identify that the first and third coding units are now available for reconstruction of the original data SN#10, rather than the first and second coding units. It is thus possible to correctly reconstruct the data SN#10 which was originally to be transmitted.

In contrast, the receiver thus also knows, in particular, whether, for example, the second coding unit has been sent or received with a delay, or whether the third coding unit has been sent on the basis of a last negative acknowledgement (NACK).

FIG. 4 shows the sequence for another exemplary embodiment of a transmission process. After a first transmission of the first coding unit SN#10, CW1, which contains errors such that it cannot be identified by the receiver, the receiver sends a reception acknowledgement SN#i, NACK to the transmitter, which can be interpreted as a negative acknowledgement, either autonomously or in respect to a request from the transmitter after a predetermined time or after a time which cannot be predetermined.

This reception acknowledgement can be initiated using generally known methods, for example by sending a list for a number of coding units, regular transmission, time-out methods, or by drawing conclusions from successful transmissions. The transmitter then sends the second coding unit SN10#, CW2 of the packet data unit SN#10. This is received in its entirety by the receiver. However, as a result of the coding method, the second coding unit SN10#, CW2 does not contain all the data from the data SN#10 which was originally to be transmitted, so that it cannot be reconstructed completely. The receiver identifies this from the information CW2 which is also transmitted relating to the second redundancy level of the transmitted data and, by retransmitting the negative reception acknowledgement SN#10, NACK, thus requests further transmission of the data SN#10 from the transmitter. The transmitter now sends the third coding unit SN#10, CW3 of the data packet SN#10 without any errors to the receiver. In the present example, the receiver uses the information CW3 which is also transmitted relating to the third redundancy level of the transmitted data SN#10 to identify that the first and third coding units are now available for reconstruction of the original data SN#10. In the present case, it is thus possible at this stage to correctly reconstruct the data SN#10 which was originally to be transmitted, so that the receiver then sends a positive reception acknowledgement ACK back to the transmitter, and starts the data reconstruction.

After the transmission of all the coding units, it is advantageously possible to resend already transmitted coding units and to link such a repeatedly transmitted coding unit with the corresponding coding unit which has already previously been received. The linking process may in this case be carried out, for example, by maximum ratio combining. In this case, it is necessary to decide which coding unit should be the first to be resent.

One possible way for the transmitter to know that a retransmission is required is to transmit to the transmitter measurement values, for example the signal-to-noise ratio of the coding units received by the receiver. The transmitter can also setup lists of the reception acknowledgements of the receiver, and can then evaluate these lists. The transmitter can then decide which coding unit it will resend.

The decision as to which of the coding units should be sent once again can be made in a particularly advantageous manner at the receiver end. To do this, the receiver explicitly requests the desired coding unit instead of a pure negative reception acknowledgement or reception message NACK. The receiver can do this on the basis of the knowledge of the information CWi which is also transmitted relating to the i-th redundancy level of the transmitted data SN#10 for already received coding units.

In particular, the request for a specific coding unit can he made by introducing a retransmission request with an appropriate signaling format from the receiver to the transmitter. If three coding levels are used, for example, it is possible to use a digital signaling format with two bits, in which, after receiving a new i-th coding unit for a data packet SN#10, the receiver also sends one of the following bit patterns in the reception acknowledgement NACK:

00, it the data packet has been detected successfully using the previously transmitted coding units;

01, if the transmitter should send the first coding unit (for the first time or once again). If a reception acknowledgement is used in which a value should or can be entered even though no transmission has as yet taken place or is planned, then the value 01 can be transmitted as a default;

10, if the transmitter should send the second coding unit (for the first time or once again);

11, if the transmitter should send the third coding unit (for the first time or once again).

In some coding methods with a rising coding level, it is possible, for example as a result of interference, for redundancy blocks which are not associated to be combined due to misinterpretation of the sequence number or of other signaling data. One consequence of this in general is that a data block such as this cannot be reconstructed once again.

A maximum number of retransmissions or a maximum number of transmission attempts can be defined for this purpose, in a particularly advantageous manner. The definition may also be made dependent on, for example, the location of the receiver or the reception time. If this number is exceeded, then selected coding units which have already been received, or all the coding units which have already been received, are explicitly requested once again in the receiver, and are advantageously deleted in advance. The transmitter does not necessarily need to be made aware of this since, by virtue of the method sequence, this advantageously relates only to the receiver. The receiver just signals that, for example, it wishes to have the first coding unit sent to it once again. In this way, in particular, the receiver can reject the already received coding units at any time, without any additional signaling complexity, and can commence the decoding method from the start.

FIG. 5 illustrates the sequence for one particularly preferred exemplary embodiment of a transmission sequence, in which the receiver can request selected coding units.

After first transmission of the first coding unit SN#10, CW1 which has so many errors that not even the identification number SN#10 of the packet data unit SN#10 has been identified by the receiver, the receiver sends a negative reception acknowledgement SN#i, CW1, NACK to the transmitter. This negative reception acknowledgement can be initiated in accordance with generally known methods, for example sending a list for a number of coding units, regular transmission, time-out methods or by drawing conclusions from successful transmissions. The transmitter then once again sends the first coding unit SN10#, CW1 of the packet data unit SN#10. This is received in its entirety by the receiver.

Next, according to a further embodiment, the transmitter sends the first coding unit SN11#, CW1 of a packet data unit SN#11. Together with a positive or negative reception acknowledgement ACK or NACK, respectively, the receiver then directly requests firstly the transmission of the second coding unit SN#11, CW2 and then the transmission of the third coding unit SN#11, CW3. After reception of the three coding units, the receiver starts to decode the data. If it finds that the received data contains errors, then it can specifically request that one or more of the coding units be transmitted once again. It can be seen from the example in FIG. 5 that the second coding unit has been received with the greatest number of errors. The retransmission of the second coding unit is accordingly requested. If the original data can be reconstructed using this, then the receiver sends a positive reception acknowledgement back to the transmitter.

1. A method for transmitting data packets (SN#10, SN#11) in a radio communications system (UMTS, GPRS) between a transmitter (BS; MS) and a receiver (MS; BS), in which
at least some of the data packets to be transmitted are each coded using different codes for a number of different coding units (CW1, CW2, CW3),
the various coding units (CW1, CW2, CW3) of at least some of these data packets are transmitted by the transmitter for receiver-end reconstruction of the data packets,
characterized in that
the receiver (MS; BS) requests from the transmitter (BS; MS) a specific one of the coding units (CW1, CW2, CW3) of a specific one of the data packets by appropriate explicit signaling.

2. The method as claimed in claim 1, in which
the transmitter transmits both information, which is associated with the coding units, about the basic data packet (SN#10, SN#11) as well as information, which is associated with the coding units, about the corresponding code (CW1, CW2, CW3), which is used to code it, to the receiver (MS; BS).

3. The method as claimed in claim 1 or 2, in which
the specific coding unit (CW1, CW2, CW3) which is requested by the receiver has already previously been transmitted by the transmitter and an unsuccessful attempt has been made to decode this received coding unit.

4. The method as claimed in one of the preceding claims, in which the request for the coding unit (CW1, CW2, CW3) by the receiver is made in conjunction with a reception acknowledgement (ACK or NACK) which can be interpreted positively or negatively, respectively, and which is transmitted by the receiver (MS; BS) to the transmitter (BS; MS).

5. The method as claimed in one of the preceding claims, in which the request for the coding unit (CW1, CW2, CW3) is made in the form of a digital bit pattern, in particular in the form of a digital bit pattern with two signaling bits for three-stage coding.

6. The method as claimed in one of the preceding claims, in which a maximum number of transmission attempts, which are repeated by the transmitter, is defined for the coding units.

7. The method as claimed in claim 6, in which after reaching the maximum number of repeated transmission attempts, a selected previously received coding unit is explicitly requested once again by the receiver (MS; BS).

8. A radio communications system for transmitting data packets (SN#10, SN#11) between a transmitter (BS; MS) and a receiver (MS; BS),
having a coding device in the transmitter (BS; MS) for coding a data packet which is to be transmitted using different codes for different coding units (CW1, CW2, CW3), which are intended for receiver-end reconstruction of the transmitted data packet,
having a decoding device in the receiver (MS; BS) for decoding the received coding units (CW1, CW2, CW3),
characterized in that
its receiver has a request device for requesting transmission of a specific coding unit (CW1, CW2, CW3), which is selected by the receiver, by means of explicit signaling.
